(19) United States
(12) Patent Application Publication
(10) Pub. No.: US 2024/0107859 A1
(43) Pub. Date: Mar. 28, 2024

(54) DISPLAY DEVICE

(71) Applicant: Samsung Display Co., LTD., Yongin-si (KR)

(72) Inventors: Sang Min HONG, Yongin-si (KR); Sun Jin JOO, Yongin-si (KR)

(21) Appl. No.: 18/219,756

(22) Filed: Jul. 10, 2023

(30) Foreign Application Priority Data
Sep. 26, 2022 (KR) 10-2022-0121403

(51) Int. Cl. H10K 59/80

(52) U.S. Cl. CPC H10K 59/873; H10K 59/879; H10K 2102/351

(57) ABSTRACT

A display device includes a substrate, a light-emitting element disposed on the substrate and including a pixel electrode, an emissive layer and a common electrode, a capping layer disposed on the common electrode of the light-emitting element, a support layer disposed on the capping layer and a thin-film encapsulation layer including a first inorganic encapsulation layer disposed on the support layer, a first organic encapsulation layer disposed on the first inorganic encapsulation layer, and a second inorganic encapsulation layer disposed on the first organic encapsulation layer, where the thin-film encapsulation layer further includes a buffer layer disposed between the first organic encapsulation layer and the second inorganic encapsulation layer and of the buffer layer includes an inorganic material, and the buffer layer has a thickness of 0.05 times to 0.3 times of a thickness the second inorganic encapsulation layer.

This application claims priority to Korean Patent Application No. 10-2022-0121403, filed on Sep. 26, 2022, and all the benefits accruing therefrom under 35 U.S.C. § 119, the content of which in its entirety is herein incorporated by reference.

### BACKGROUND

### 1. Field

The disclosure relates to a display device.

### 2. Description of the Related Art

As the information-oriented society evolves, display devices are widely used in various fields. For example, display devices are being employed by a variety of electronic devices such as smart phones, digital cameras, laptop computers, navigation devices, and smart televisions. Display devices may be flat-panel display devices such as a liquid-crystal display device, a field emission display device, and an organic light-emitting display device. Among such flat panel display devices, a light-emitting display device includes a light-emitting element that can emit light on its own, so that each of the pixels of the display panel can emit light by themselves. Accordingly, a light-emitting display device can display images without using a backlight unit that supplies light to the display panel.

Such a light-emitting display device typically include a light-emitting element including an anode, an emissive layer, and a cathode. Such an emissive layer may be substantially vulnerable to moisture or oxygen. If moisture or oxygen permeates from an outside, the emissive layer may be deteriorated, and defects may arise such as dark spots and pixel shrinkage. To address such issues, an encapsulation unit is typically used to protect light-emitting elements.

### SUMMARY

Embodiments of the disclosure provide a display device with improved efficiency of external light.

According to an embodiment, A display device includes a substrate, a light-emitting element disposed on the substrate and including a pixel electrode, an emissive layer and a common electrode, a capping layer disposed on the common electrode of the light-emitting element, a support layer disposed on the capping layer and a thin-film encapsulation layer including a first inorganic encapsulation layer disposed on the support layer, a first organic encapsulation layer disposed on the first inorganic encapsulation layer, and a second inorganic encapsulation layer disposed on the first organic encapsulation layer, where the thin-film encapsulation layer further includes a buffer layer disposed between the first organic encapsulation layer and the second inorganic encapsulation layer, the buffer layer includes an inorganic material, and the buffer layer has a thickness of 0.05 times to 0.3 times of a thickness the second inorganic encapsulation layer.

In an embodiment, the second inorganic encapsulation layer may have a thickness of about 6,000 Å to about 8,000 Å, and the buffer layer may have a thickness of about 300 Å to about 500 Å.

In an embodiment, the second inorganic encapsulation layer may have a thickness of about 6,000 Å to about 8,000 Å, and the buffer layer may have a thickness of about 1,600 Å to about 1,800 Å.

In an embodiment, the buffer layer may have a refractive index greater than a refractive index of the first organic encapsulation layer and less than a refractive index of the second inorganic encapsulation layer.

In an embodiment, the first organic encapsulation layer may have a refractive index of about 1.50 to about 1.60, the buffer layer may have a refractive index of about 1.60 to about 1.80, and the second inorganic encapsulation layer may have a refractive index of about 1.85 to about 1.95.

In an embodiment, the second inorganic encapsulation layer may include silicon nitride (SiNx).

In an embodiment, the thickness of the buffer layer may be equal to that of the support layer.

In an embodiment, the support layer may have a thickness of about 300 Å to about 500 Å.

In an embodiment, the support layer may include lithium fluoride (LiF).

In an embodiment, the buffer layer may be disposed directly on the first organic encapsulation layer.

According to an embodiment, a display device includes a substrate, a light-emitting element disposed on the substrate and including a pixel electrode, an emissive layer and a common electrode, a capping layer disposed on the common electrode of the light-emitting element, a support layer disposed on the capping layer and a thin-film encapsulation layer including first inorganic encapsulation layer disposed on the support layer, a first organic encapsulation layer disposed on the first inorganic encapsulation layer, a buffer layer disposed on the first organic encapsulation layer, and a second inorganic encapsulation layer disposed on the buffer layer, where the buffer layer includes an inorganic material and has a multilayer structure including a first buffer layer and a second buffer layer having different refractive indices from each other.

In an embodiment, the first buffer layer may have a refractive index greater than a refractive index of the first organic encapsulation layer, and the second buffer layer may have a refractive index greater than the refractive index of the first buffer layer.

In an embodiment, the first organic encapsulation layer may have a refractive index of about 1.50 to about 1.60, the first buffer layer may have a refractive index of about 1.60 to about 1.70, the second buffer layer may have a refractive index of about 1.70 to about 1.80, and the second inorganic encapsulation layer may have a refractive index of about 1.85 to about 1.95.

In an embodiment, the second inorganic encapsulation layer includes silicon nitride (SiNx).

In an embodiment, the second inorganic encapsulation layer may have a thickness of about 6,000 Å to about 8,000 Å, and the buffer layer may have a thickness of about 1,400 Å to about 1,600 Å.

In an embodiment, the first buffer layer may have a thickness of about 900 Å to about 1,100 Å, and the second buffer layer may have a thickness of about 400 Å to about 600 Å.

In an embodiment, the second inorganic encapsulation layer may have a thickness of about 6,000 Å to about 8,000 Å, and the buffer layer may have a thickness of about 2,650 Å to about 2,850 Å.

In an embodiment, the first buffer layer may have a thickness of about 1,650 Å to about 1,850 Å, and the second buffer layer may have a thickness of about 1,000 Å to about 1,200 Å.

In an embodiment, the support layer may include lithium fluoride (LiF) and may have a refractive index of about 1.4.

In an embodiment, the first inorganic encapsulation layer has a refractive index of about 1.5, and the capping layer has a refractive index of about 2.0.

According to embodiments of the disclosure, it is possible to improve the efficiency of external light in a display device by a buffer layer included in an encapsulation layer.

However, the effects of embodiments of the disclosure are not limited to the aforementioned effects, and various other effects are included in the specification.

### BRIEF DESCRIPTION OF THE DRAWINGS

The above and other features of embodiments of the disclosure will become more apparent by describing in detail embodiments thereof with reference to the attached drawings, in which:

FIG. 1 is a perspective view of an electron device according to an embodiment of the disclosure.

FIG. 2 is a perspective view showing a display device included in an electron device according to an embodiment of the disclosure.

FIG. 3 is a cross-sectional view of the display device of FIG. 2 seen from a side.

FIG. 4 is a plan view showing a display layer of a display device according to an embodiment of the disclosure.

FIG. 5 is a cross-sectional view showing a part of a display device according to an embodiment of the disclosure.

FIG. 6 is a cross-sectional view showing a stacked structure of a light-emitting element and an encapsulation layer of a display device according to an embodiment.

FIG. 7 is a cross-sectional view showing a stacked structure of a light-emitting element and an encapsulation layer of a display device according to an alternative embodiment.

FIG. 8 is a graph showing results of a prediction simulation of a change in luminous efficiency depending on the thickness of a buffer layer.

FIG. 9 is a cross-sectional view showing a part of a display device according to an alternative embodiment of the disclosure.

FIGS. 10 to 13 are cross-sectional views showing a stacked structure of a light-emitting element and an encapsulation layer of a display device according to alternative embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings.

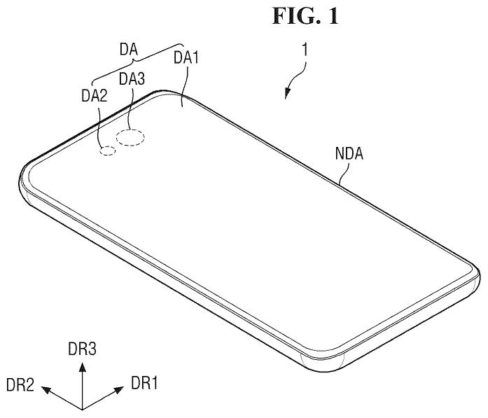

FIG. 1 is a plan view of a display device according to an embodiment of the disclosure.

Referring to FIG. 1, an electron device 1 displays a moving image or a still image. The electron device 1 may refer to any electronic device that provides a display screen. In an embodiment, for example, the electron device 1 may include a television set, a laptop computer, a monitor, an electronic billboard, the Internet of Things devices, a mobile phone, a smart phone, a tablet personal computer (PC), an electronic watch, a smart watch, a watch phone, a head-mounted display device, a mobile communications terminal, an electronic notebook, an electronic book, a portable multimedia player (PMP), a navigation device, a game console and a digital camera, a camcorder, etc.

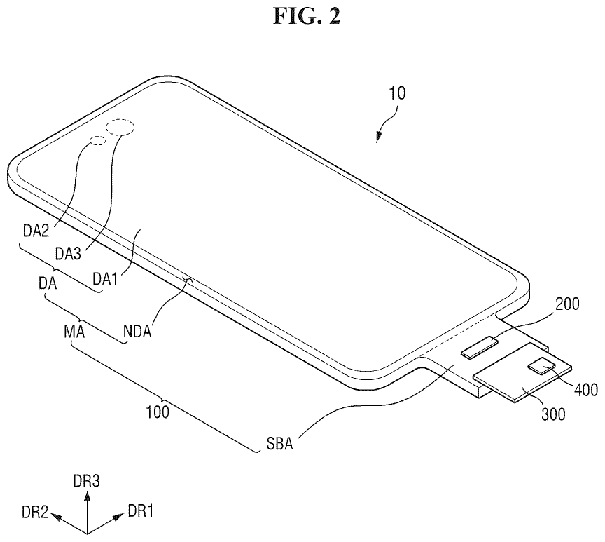

The electron device 1 may include a display device 10 (see FIG. 2) for providing a display screen. In an embodiment, the display device may be an inorganic light-emitting diode display device, an organic light-emitting display device, a quantum-dot light-emitting display device, a plasma display device, or a field emission display device, for example. In the following description, embodiments where the display device 10 is an organic light-emitting diode display device will be mainly described in detail, but the disclosure is not limited thereto. Any other display device may be employed as long as the technical idea of the disclosure can be equally applied.

The shape of the electron device 1 may be modified in a variety of ways. In an embodiment, for example, the electron device 1 may have one of various shapes such as a rectangle with longer lateral sides, a rectangle with longer vertical sides, a square, a quadrangle with rounded corners (vertices), other polygons or a circle, for example. The shape of a display area DA of the electron device 1 may also be similar to the overall shape of the electron device 1. In an embodiment, as shown in FIG. 1, the electron device 1 has a rectangular shape with the longer sides in a second direction DR2.

The electron device 1 may include the display area DA and a non-display area NDA. In the display area DPA, images can be displayed. In the non-display area NDA, images are not displayed. The display area DPA may be referred to as an active area, while the non-display area NDA may also be referred to as an inactive area. The display area DA may generally occupy the center of the electron device 1.

In an embodiment, the display area DA may include a first display area DA1, a second display area DA2 and a third display area DA3. In such an embodiment, components for performing a variety of features to the electronic device 1 may be disposed in (or to overlap) the second display area DA2 and the third display area DA3. In such an embodiment, the second display area DA2 and the third display area DA3 may be referred to as component areas.

FIG. 2 is a perspective view showing a display device included in an electron device according to an embodiment of the disclosure.

Referring to FIG. 2, an embodiment of the electron device 1 may include a display device 10. The display device 10 may provide a display screen where images are displayed in the electron device 1. The display device 10 may have a shape similar to that of the electronic device 1 when viewed from the top. In an embodiment, for example, the display device 10 may have a shape similar to a rectangle having shorter sides in the first direction DR1 and longer sides in the second direction DR2. In an embodiment, the corners where the shorter sides in the first direction DR1 meet the longer sides in the second direction DR2 may be rounded with a predetermined curvature. It should be understood, however, that the disclosure is not limited thereto. In an alternative embodiment, the corners may be formed at a right angle. The shape of the display device 10 when viewed from the top is not limited to a quadrangular shape, but may be formed in a shape similar to other polygonal shapes, a circular shape, or an elliptical shape.

The display device 10 may include a display panel 100, a display driver 200, a circuit board 300 and a touch driver 400.

The display panel 100 may include a main area MA and a subsidiary area SBA.

The main area MA may include the display area DA including pixels for displaying images, and the non-display area NDA located around the display area DA. The display area DA may include the first display area DA1, the second display area DA2 and the third display area DA3. The display area DA may emit light from a plurality of emission areas or a plurality of opening areas. In an embodiment, for example, the display panel 100 may include a pixel circuit including switching elements, a pixel-defining layer that defines the emission areas or the opening areas, and a self-light-emitting element.

In an embodiment, for example, the self-light-emitting element may include, but is not limited to, at least one selected from an organic light-emitting diode including an organic emissive layer, a quantum-dot light-emitting diode (quantum LED) including a quantum-dot emissive layer, an inorganic light-emitting diode (inorganic LED) including an inorganic semiconductor, and a micro light-emitting diode (micro LED).

The non-display area NDA may be disposed on the outer side of the display area DA. The non-display area NDA may be defined as the edge area of the main area MA of the display panel 100. The non-display area NDA may include a gate driver (not shown) that applies gate signals to gate lines, and fan-out lines (not shown) that connect the display driver 200 with the display area DA.

The subsidiary area SBA may extend from one side of the main area MA. The subsidiary area SUB may include a flexible material that can be bent, folded, or rolled. In an embodiment, for example, in a state where the subsidiary area SBA is bent, the subsidiary area SBA may overlap the main area MA in a thickness direction (third direction DR3). The subsidiary area SBA may include pads connected to the display driver 200 and the circuit board 300. According to another embodiment, the subsidiary area SBA may be omitted, and the display driver 200 and the pads may be disposed (e.g., directly formed) in the non-display area NDA.

The display driver 200 may output signals and voltages for driving the display panel 100. The display driver 200 may supply data voltages to data lines. The display driver 200 may apply a supply voltage to a voltage line and may supply gate control signals to the gate driver. The display driver 200 may be implemented as an integrated circuit (IC) and may be attached on the display panel 100 by a chip-on-glass (COG) technique, a chip-on-plastic (COP) technique, or ultrasonic bonding. In an embodiment, for example, the display driver 200 may be disposed in the subsidiary area SBA and may overlap the main area MA in the thickness direction as the subsidiary area SBA is bent. In an alternative embodiment, for example, the display driver 200 may be mounted on the circuit board 300.

The circuit board 300 may be attached on the pads of the display panel 100 using an anisotropic conductive film (ACF). Lead lines of the circuit board 300 may be electrically connected to the pads of the display panel 100. The circuit board 300 may be a flexible printed circuit board (FPCB), a printed circuit board (PCB), or a flexible film such as a chip-on-film (COF).

The touch driver 400 may be mounted on the circuit board 300. The touch driver 400 may be connected to a touch sensing unit of the display panel 100. The touch driver 400 may supply a touch driving signal to a plurality of touch electrodes of the touch sensing unit and may sense a change in the capacitance between the plurality of touch electrodes. In an embodiment, for example, the touch driving signal may be a pulse signal having a predetermined frequency. The touch driver 400 may determine whether there is an input and may find the coordinates of the input based on the amount of the change in the capacitance between the touch electrodes. The touch driver 400 may be implemented as an integrated circuit (IC).

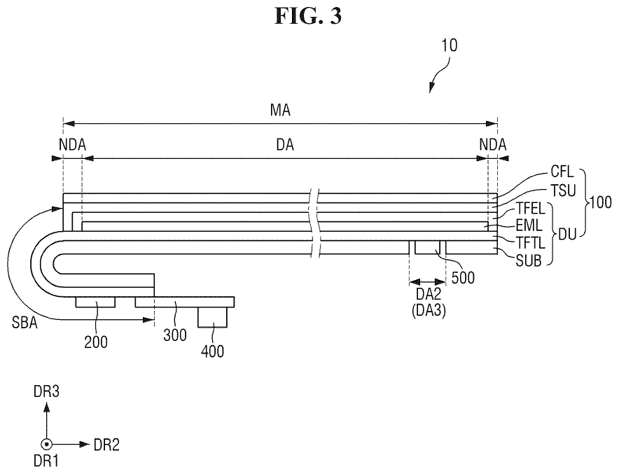

FIG. 3 is a cross-sectional view of the display device of FIG. 2 seen from a side.

Referring to FIG. 3, in an embodiment, the display panel 100 may include a display layer DU, a touch sensing layer TSU, and a color filter layer CFL. The display layer DU may include a substrate SUB, a thin-film transistor layer TFTL, an emission material layer EML and a thin-film encapsulation layer TFEL.

The substrate SUB may be a base substrate or a base member. The substrate SUB may be a flexible substrate that can be bent, folded, or rolled. In an embodiment, for example, the substrate SUB may include, but is not limited to, a polymer resin such as polyimide PI. In an alternative embodiment, the substrate SUB may include a glass material or a metal material.

The thin-film transistor layer TFTL may be disposed on the substrate SUB. The thin-film transistor layer TFTL may include a plurality of thin-film transistors included in pixel circuits of pixels. The thin-film transistor layer TFTL may include gate lines, data lines, voltage lines, gate control lines, fan-out lines for connecting the display driver 200 with the data lines, lead lines for connecting the display driver 200 with the pads, etc. Each of the thin-film transistors may include a semiconductor region, a source electrode, a drain electrode, and a gate electrode. In an embodiment, for example, where the gate driver is formed on one side of the non-display area NDA of the display panel 100, the gate driver may include thin-film transistors.

The thin-film transistor layer TFTL may be disposed in the display area DA, the non-display area NDA and the subsidiary area SBA. The thin-film transistors in each of the pixels, the gate lines, the data lines and the voltage lines in the thin-film transistor layer TFTL may be disposed in the display area DA. The gate control lines and the fan-out lines in the thin-film transistor layer TFTL may be disposed in the non-display area NDA. The lead lines of the thin-film transistor layer TFTL may be disposed in the subsidiary area SBA.

The emission material layer EML may be disposed on the thin-film transistor layer TFTL. The emission material layer EML may include a plurality of light-emitting elements each including a first electrode, a second electrode and an emissive layer to emit light, and a pixel-defining layer for defining the pixels. The plurality of light-emitting elements in the emission material layer EML may be disposed in the display area DA.

According to an embodiment of the disclosure, the emissive layer may be an organic emissive layer including an organic material. The emissive layer may include a hole transporting layer, an organic light-emitting layer and an electron transporting layer. When the first electrode receives a voltage and the second electrode receives a cathode voltage through the thin-film transistors on the thin-film transistor layer TFTL, the holes and electrons may move to the organic light-emitting layer through the hole transporting layer and the electron transporting layer, respectively, such that the holes and electrons are combined with each other in the organic light-emitting layer to emit light.

According to an alternative embodiment, the light-emitting elements may include quantum-dot light-emitting diodes each including a quantum-dot emissive layer, inorganic light-emitting diodes each including an inorganic semiconductor, or micro light-emitting diodes.

The thin-film encapsulation layer TFEL may cover the upper and side surfaces of the emission material layer EML, and can protect the emission material layer EML. The thin-film encapsulation layer TFEL may include at least one inorganic layer and at least one organic layer for encapsulating the emission material layer EML.

The touch sensing layer TSU may be disposed on the thin-film encapsulation layer TFEL. The touch sensing layer TSU may include a plurality of touch electrodes for sensing a user's touch by capacitive sensing, and touch lines connecting the plurality of touch electrodes with the touch driver 400. In an embodiment, for example, the touch sensing layer TSU may sense a user's touch by mutual capacitance sensing or self-capacitance sensing.

In an alternative embodiment, for example, the touch sensing layer TSU may be disposed on a separate substrate disposed on the display layer DU. In such an embodiment, the substrate supporting the touch sensing layer TSU may be a base member encapsulating the display layer DU.

The plurality of touch electrodes of the touch sensing layer TSU may be disposed in a touch sensor area overlapping the display area DA. The touch lines of the touch sensing layer TSU may be disposed in a touch peripheral area overlapping the non-display area NDA.

The color filter layer CFL may be disposed on the touch sensing layer TSU. The color filter layer CFL may include a plurality of color filters associated with the plurality of emission areas, respectively. Each of the color filters may selectively transmit light of a particular wavelength and block or absorb lights of other wavelengths. The color filter layer CFL may absorb some of lights introduced from the outside of the display device 10 to reduce the reflection of external light. Accordingly, the color filter layer CFL can prevent distortion of colors due to the reflection of external light.

Since the color filter layer CFL is disposed directly on the touch sensing layer TSU, the display device 10 may not include a separate substrate for the color filter layer CFL. Therefore, the thickness of the display device 10 can be relatively small.

In some embodiments, the display device 10 may further include an optical device 500. The optical device 500 may be disposed in (or to overlap) the second display area DA2 or the third display area DA3. The optical device 500 may emit or receive light in infrared, ultraviolet, and visible ranges. In an embodiment, for example, the optical device 500 may be an optical sensor that senses light incident on the display device 10, such as a proximity sensor, an illuminance sensor, a camera sensor and an image sensor.

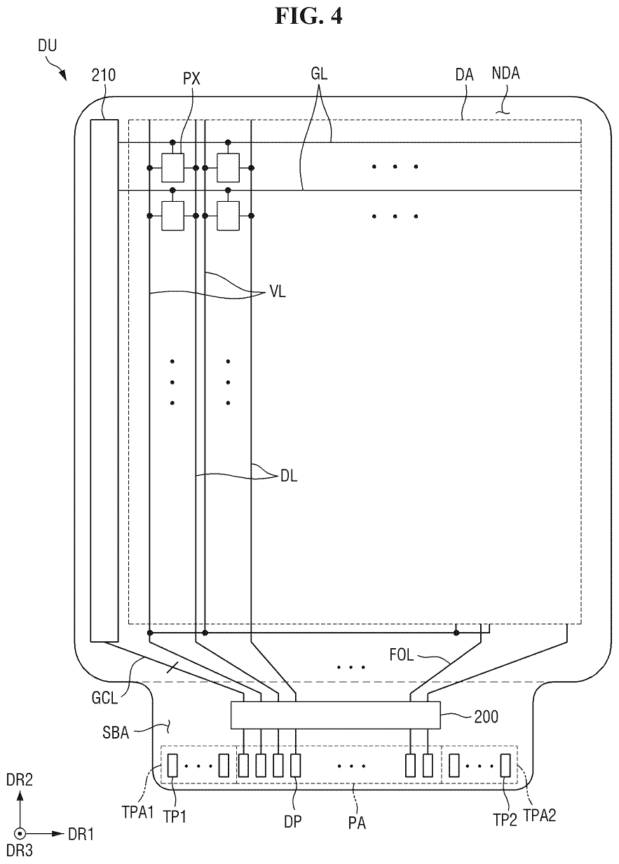

FIG. 4 is a plan view showing a display layer of a display device according to an embodiment of the disclosure.

Referring to FIG. 4, in an embodiment, the display layer DU may include a display area DA and a non-display area NDA.

The display area DA may be disposed at the center of display device 10. In the display area DA, a plurality of pixels PX, a plurality of gate lines GL, a plurality of data lines DL and a plurality of voltage lines may be disposed. Each of the plurality of pixels PX may be defined as the minimum or basic unit that outputs light.

The plurality of gate lines GL may supply the gate signals received from the gate driver 210 to the plurality of pixels PX. The plurality of gate lines GL may extend in the first direction DR1 and may be spaced apart from one another in the second direction DR2 intersecting the first direction DR1.

The plurality of data lines DL may supply the data voltages received from the display driver 200 to the plurality of pixels PX. The plurality of data lines DL may extend in the second direction DR2 and may be spaced apart from one another in the first direction DR1.

The plurality of voltage lines VL may supply the supply voltage received from the display driver 200 to the plurality of pixels PX. The supply voltage may be at least one selected from a driving voltage, an initialization voltage, a reference voltage and a low-level voltage. The plurality of voltage lines VL may extend in the second direction DR2 and may be spaced apart from one another in the first direction DR1.

The non-display area NDA may surround the display area DA. In the non-display area NDA, the gate driver 210, fan-out lines FOL, and gate control lines GCL may be disposed. The gate driver 210 may generate a plurality of gate signals based on the gate control signal, and may sequentially supply the plurality of gate signals to the plurality of gate lines GL in a predetermined order.

The fan-out lines FOL may extend from the display driver 200 to the display area DA. The fan-out lines FOL may supply the data voltage received from the display driver 200 to the plurality of data lines DL.

A gate control line GCL may extend from the display driver 200 to the gate driver 210. The gate control line GCL may supply the gate control signal received from the display driver 200 to the gate driver 210.

The subsidiary area SBA may include the display driver 200, a pad area DPA, and first and second touch pad areas TPA1 and TPA2.

The display driver 200 may output signals and voltages for driving the display panel 100 to the fan-out lines FOL. The display driver 200 may supply data voltages to the data lines DL through the fan-out lines FOL. The data voltages may be applied to the plurality of pixels PX, so that the luminance of the plurality of pixels PX may be controlled. The display driver 200 may supply a gate control signal to the gate driver 210 through the gate control line GCL.

The pad area DPA, the first touch pad area TPA1 and the second touch pad area TPA2 may be disposed at the edge of the subsidiary area SBA. The pad area PA, the first touch pad area TPA1 and the second touch pad area TPA2 may be electrically connected to the circuit board 300 using a material such as an anisotropic conductive film and a self assembly anisotropic conductive paste (SAP).

The pad area DPA may include a plurality of display pads DPA. The plurality of display pads DP may be connected to a graphic system through the circuit board 300. The plurality of display pads DP may be connected to the circuit board 300 to receive digital video data and may supply digital video data to the display driver 200.

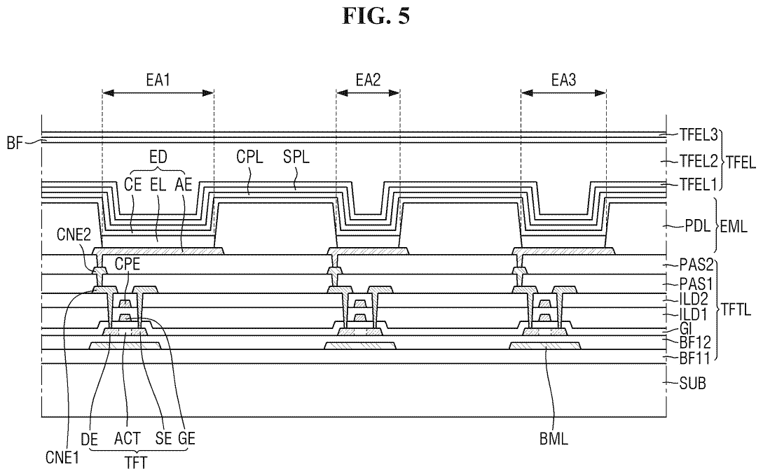

FIG. 5 is a cross-sectional view showing a display device according to an embodiment of the disclosure. FIG. 5 is a cross-sectional view of a part of the display device 10, specifically, the substrate SUB, the thin-film transistor layer TFTL, the emission material layer EML, and the thin-film encapsulation layer TFEL of the display layer DU.

Referring to FIG. 5, the substrate SUB may be a base substrate or a base member. The substrate SUB may be a flexible substrate that can be bent, folded, or rolled. In an embodiment, for example, the substrate SUB may include, but is not limited to, a polymer resin such as polyimide PI. In an alternative embodiment, for example, the substrate SUB may include a glass material or a metal material.

The thin-film transistor layer TFTL may include a first buffer layer BF11, a bottom metal layer BML, a second buffer layer BF12, a thin-film transistor TFT, a gate insulator GI, a first interlayer dielectric layer ILD1, a capacitor electrode CPE, a second interlayer dielectric layer ILD2, a first connection electrode CNE1, a first passivation layer PAS1, a second connection electrode CNE2 and a second passivation layer PAS2.

The first buffer layer BF11 in the thin-film transistor layer TFTL (hereinafter, will be referred to as “first TR buffer layer”) may be disposed on the substrate SUB. The first TR buffer layer BF11 may include an inorganic film capable of preventing permeation of air or moisture. In an embodiment, for example, the first TR buffer layer BF11 may include a plurality of inorganic films stacked on one another alternately.

The bottom metal layer BML may be disposed on the first TR buffer layer BF11.

For example, the bottom metal layer BML may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second buffer layer BF12 in the thin-film transistor layer TFTL (hereinafter, will be referred to as “second TR buffer layer”) may cover the first TR buffer layer BF11 and the bottom metal layer BML. The second TR buffer layer BF12 may include an inorganic film capable of preventing permeation of air or moisture. In an embodiment, for example, the second TR buffer layer BF12 may include a plurality of inorganic films stacked on one another alternately.

The thin-film transistor TFT may be disposed on the second TR buffer layer BF12 and may form a pixel circuit of each of a plurality of pixels. In an embodiment, for example, the thin-film transistor TFT may be a driving transistor or a switching transistor of the pixel circuit. The thin-film transistor TFT may include a semiconductor layer ACT, a source electrode SE, a drain electrode DE and a gate electrode GE.

The semiconductor layer ACT may be disposed on the second TR buffer layer BF12. The semiconductor layer ACT may overlap the bottom metal layer BML and the gate electrode GE in a thickness direction of the substrate SUB and may be insulated from the gate electrode GE by the gate insulator GI. The material of parts of the semiconductor layer ACT may be made conductive to form the source electrode SE and the drain electrode DE.

The gate electrode GE may be disposed on the gate insulator GI. The gate electrode GE may overlap the semiconductor layer ACT with the gate insulating layer GI interposed therebetween.

The gate insulator GI may be disposed on the semiconductor layer ACT. thickness direction example, the gate insulator GI may cover the semiconductor layer ACT and the second buffer layer BF2, and may insulate the semiconductor layer ACT from the gate electrode GE. The gate insulator GI may be provided with a contact hole through which the first connection electrode CNE1 passes.

The first interlayer dielectric layer ILD1 may cover the gate electrode GE and the gate insulator GI. The first interlayer dielectric layer ILD1 may be provided with a contact hole through which the first connection electrode CNE1 passes. The contact holes of the first interlayer dielectric layer ILD1 may be connected to the contact holes of the gate insulator GI and the contact holes of the second interlayer dielectric layer ILD2.

The capacitor electrode CPE may be disposed on the first interlayer dielectric layer ILD1. The capacitor electrode CPE may overlap the gate electrode GE in the thickness direction. The capacitor electrode CPE and the gate electrode GE may form or collectively define a capacitance.

The second interlayer dielectric layer ILD2 may cover the capacitor electrode CPE and the first interlayer dielectric layer ILD1. The second interlayer dielectric layer ILD2 may be provided with a contact hole through which the first connection electrode CNE1 passes. The contact hole of the second interlayer dielectric layer ILD2 may be connected to the contact hole of the first interlayer dielectric layer ILD1 and the contact hole of the gate insulator GI.

The first connection electrode CNE1 may be disposed on the second interlayer dielectric layer ILD2. The first connection electrode CNE1 may electrically connect the drain electrode DE of the thin-film transistor TFT with the second connection electrode CNE2. The first connection electrode CNE1 may be inserted into a contact hole defined or formed in the second interlayer dielectric layer ILD2, the first interlayer dielectric layer ILD1, and the gate insulator GI to be in contact with the drain electrode DE of the thin-film transistor TFT.

The first passivation layer PAS1 may cover the first connection electrode CNE1 and the second interlayer dielectric layer ILD2. The first passivation layer PAS1 can protect the thin-film transistor TFT. The first passivation layer PAS1 may be provided with a contact hole through which the second connection electrode CNE2 passes.

The second connection electrode CNE2 may be disposed on the first passivation layer PAS1. The second connection electrode CNE2 may electrically connect the first connection electrode CNE1 with a pixel electrode AE of a light-emitting element ED. The second connection electrode CNE2 may be inserted into a contact hole defined or formed in the first passivation layer PAS1 to be in contact with the first connection electrode CNE1.

The second passivation layer PAS2 may cover the second connection electrode CNE2 and the first passivation layer PAS1. The second passivation PAS2 may be provided with a contact hole through which the pixel electrode AE of the light-emitting element ED passes.

The emission material layer EML may be disposed on the thin-film transistor layer TFTL. The emission material layer EML may include a light-emitting element ED and a pixel-defining layer PDL. The light-emitting element ED may include the anode electrode AE, an emissive layer EL, and a common electrode CE.

The pixel electrode AE may be disposed on the second passivation layer PAS2. The pixel electrode AE may be disposed in line with one of openings OPE1, OPE2 and OPE3 defined in the pixel-defining layer PDL. The pixel electrode AE may be electrically connected to the drain electrode DE of the thin-film transistor TFT through the first and second connection electrodes CNE1 and CNE2.

The emissive layer EL may be disposed on the pixel electrode AE. In an embodiment, for example, the emissive layer EL may be, but is not limited to, an organic emissive layer made of an organic material. in an embodiment where the emissive layer EL is an organic emissive layer, when the thin-film transistor applies a predetermined voltage to the pixel electrode AE of the light-emitting element ED and the common electrode CE of the light-emitting element ED receives a common voltage or cathode voltage, the holes and electrons may move to the emissive layer EL through the hole transporting layer and the electron transporting layer, respectively, and the holes and electrons are combined with each other in the emissive layer EL to emit light.

The common electrode CE may be disposed on the emissive layer EL. In an embodiment, for example, the common electrode CE may be implemented as an electrode common to all pixels, instead of being disposed as a separated electrode for each of the pixels. The common electrode CE may be disposed on the emissive layer EL in first to third emission areas EA1, EA2 and EA3, and may be disposed on the pixel-defining layer PDL in the other areas than the first to third emission areas EA1, EA2 and EA3.

The common electrode CE may receive a common voltage or a low-level voltage. When the pixel electrode AE receives the voltage equal to the data voltage and the common electrode CAT receives the low-level voltage, a potential difference is formed between the pixel electrode AE and the common electrode CE, so that the emissive layer EL can emit light.

The pixel-defining layer PDL may be provided with a plurality of openings OPE1, OPE2 and OPE3, and may be disposed on the second passivation layer PAS2 and a part of the pixel electrode AE. In an embodiment, the first opening OPE1, the second opening OPE2 and the third opening OPE3 may be defined through the pixel-defining layer PDL, and each of the openings OPE1, OPE2 and OPE3 is a part of the pixel electrode AE. As described above, the openings OPE1, OPE2 and OPE3 of the pixel-defining layer PDL may define the first to third emission areas EA1, EA2 and EA3, respectively, which may have different areas or sizes from each other. The pixel-defining layer PDL may separate and insulate the pixel electrode AE of one of the plurality of light-emitting elements ED from the pixel electrode of another one of the light-emitting elements ED. The pixel-defining layer PDL may include a light-absorbing material to prevent light reflection. In an embodiment, for example, the pixel-defining layer PDL may include a polyimide (PO-based binder, and pigments in which red, green and blue are mixed. Alternatively, the pixel-defining layer PDL may include a cardo-based binder resin and a mixture of lactam black pigment and blue pigment. Alternatively, the pixel-defining layer PDL may include carbon black.

A capping layer CPL may be disposed on the common electrode CE. The capping layer CPL may include at least one selected from an inorganic material and an organic material having light transmittance to prevent oxygen or moisture from permeating into the emission material layer EML. In addition, the capping layer CPL may facilitate the light generated in the emissive layer to efficiently exit to an outside. In an embodiment, the capping layer CPL may include aluminum oxide, titanium oxide, tantalum oxide, hafnium oxide, zinc oxide, silicon oxide, silicon nitride, and/or silicon oxynitride.

A support layer SPL may be disposed on the capping layer CPL. As will be described later, the support layer SPL together with the capping layer CPL may function as optical layers capable of improving the luminous efficiency of the light-emitting elements ED or controlling viewing angles. In an embodiment, a material included in the support layer SPL is not particularly limited, and may include, for example, lithium fluoride (LiF).

The thin-film encapsulation layer TFEL may be disposed on the support layer SPL to cover the plurality of light-emitting elements ED. The thin-film encapsulation layer TFEL may include at least one inorganic layer to prevent permeation of oxygen or moisture into the emission material layer EML. The thin-film encapsulation layer TFEL may include at least one organic layer to protect the emission material layer EML from foreign substances such as dust.

In an embodiment, the thin-film encapsulation layer TFEL may include a first inorganic encapsulation layer TFEL1, a first organic encapsulation layer TFEL2 disposed on the first inorganic encapsulation layer TFEL1, a buffer layer BF disposed on the first organic encapsulation layer TFEL2, and a second inorganic encapsulation layer TFEL3 disposed on the buffer layer BF.

Each of the first inorganic encapsulation layer TFEL1 and the second inorganic encapsulation layer TFEL3 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

The first organic encapsulation layer TFEL2 may include a polymer-based material. The polymer-based material may include an acrylic resin, an epoxy resin, polyimide, polyethylene, etc. In an embodiment, for example, the first organic encapsulation layer TFEL2 may include an acrylic resin, such as polymethyl methacrylate and polyacrylic acid. The first organic encapsulation layer TFEL2 may be formed by curing a monomer or by applying a polymer.

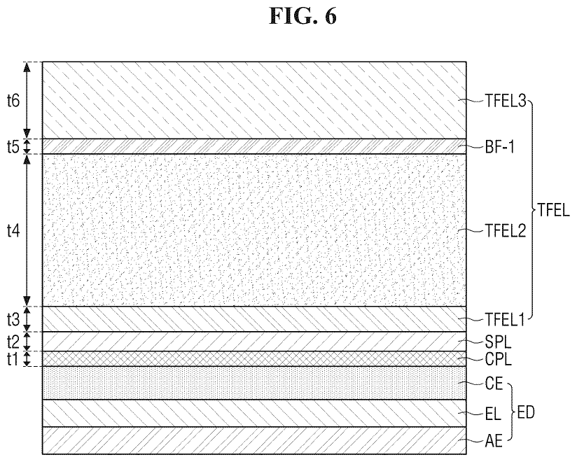

The buffer layer BF is disposed between the first organic encapsulation layer TFEL2 and the second inorganic encapsulation layer TFEL3. The buffer layer BF may include an inorganic film that can prevent the permeation of air or moisture. The buffer layer BF may cover the first organic encapsulation layer TFEL2. The buffer layer BF will hereinafter be described in greater detail with reference to FIGS. 6 to 8.

FIG. 6 is a cross-sectional view showing a stacked structure of a light-emitting element and an encapsulation layer of a display device according to an embodiment.

Referring to FIG. 6, an embodiment of the display device 10 may have a structure in which a light-emitting element ED and a plurality of inorganic or organic films are stacked thereon. In an embodiment, for example, the display device 10 may include a capping layer CPL, a support layer SPL, a first inorganic encapsulation layer TFEL1, a first organic encapsulation layer TFEL2, a buffer layer BF-1 and a second inorganic encapsulation layer TFEL3 sequentially disposed on the common electrode CE of the light-emitting element ED. Each of the capping layer CPL disposed directly on the light-emitting element ED and the support layer SPL disposed thereon may include an inorganic insulating material, but the capping layer CPL and the support layer SPL may have different materials or different refractive indexes and thicknesses from each other. Lights output from the light-emitting element ED exits through the capping layer CPL and the support layer SPL. As the capping layer CPL and the support layer SPL have different refractive indices from each other, reflection of lights may occur at the interface therebetween. In an embodiment of the display device 10, optical layers capable of reflecting lights are disposed on the light-emitting elements ED using layers having different refractive indices from each other, so that the luminous efficiency (or emission efficiency) and viewing angle of the light-emitting elements ED can be controlled as desired. The display device 10 may include more optical layers using other layers in addition to the capping layer CPL and the support layer SPL.

According to an embodiment of the disclosure, the display device 10 may include the thin-film encapsulation layer TFEL including a first inorganic encapsulation layer TFEL1 disposed on the support layer SPL, a first organic encapsulation layer TFEL2 disposed on the first inorganic encapsulation layer TFEL1, and a second inorganic encapsulation layer TFEL3 disposed on the first organic encapsulation layer TFEL2. In addition to the capping layer CPL and the support layer SPL, the first inorganic encapsulation layer TFEL1, the first organic encapsulation layer TFEL2, the buffer layer BF-1, and the second inorganic encapsulation layer TFEL3 can reflect light at the interfaces therebetween, so that the first inorganic encapsulation layer TFEL1, the first organic encapsulation layer TFEL2, the buffer layer BF-1, and the second inorganic encapsulation layer TFEL3 may function as the optical layers. The first inorganic encapsulation layer TFEL1, the first organic encapsulation layer TFEL2, the buffer layer BF-1 and the second inorganic encapsulation layer TFEL3 may include different materials from each other and may have different refractive indexes and thicknesses from each other. Lights emitted in the light-emitting element ED may pass through the layers sequentially from the capping layer CPL and exit upward. While the lights pass through the interfaces between the layers having different refractive indices from each other, the lights may be reflected and refracted partially and repeatedly. By adjusting the refractive index and thickness of each of the layers disposed on the light-emitting element ED, the emission efficiency and viewing angles of the lights output from the light-emitting element ED can be controlled as desired.

Hereinafter, the capping layer CPL, the support layer SPL, the first inorganic encapsulation layer TFEL1, the first organic encapsulation layer TFEL2, the buffer layer BF-1, and the second inorganic encapsulation layer TFEL3, which act or function as optical layers disposed on the light-emitting element ED, will be described in detail.

The capping layer CPL may include at least one selected from silicon oxide (SiOx), silicon nitride (SiNx), and silicon oxynitride (SiOxNy). The capping layer CPL may have a refractive index n1 of about 1.60 to about 2.30, and a thickness t1 of about 500 angstrom (A) to about 1,500 Å. In an embodiment, for example, the capping layer CPL may have the refractive index n1 of about 2.0 and the thickness t1 of about 850 Å. Herein, the phrase “refractive index/thickness of A to B” means “refractive index/thickness in a range of A to B”, “refractive index/thickness greater than A and less than B” or “refractive index/thickness greater than or equal to A and less than or equal to B.”

According to an embodiment, in the display device 10, adjacent ones of the inorganic insulating layers disposed on the capping layer CPL may have different refractive indices from each other, and an inorganic insulating layer having a high refractive index and an inorganic insulating layer having a low refractive index may be alternately arranged. In an embodiment, for example, the capping layer CPL may be a high refractive layer having a higher refractive index, and the support layer SPL disposed thereon may be a low refractive layer having a relatively lower refractive index. A first inorganic insulating layer 110 of the first inorganic encapsulation layer TFEL1 may be a high refractive layer.

The support layer SPL may be disposed on the capping layer CPL and have a lower refractive index than that of the capping layer CPL. In an embodiment, for example, the support layer SPL may have a refractive index n2 of about 1.20 to about 1.62 and a thickness t2 of about 200 Å to about 1400 Å. The support layer SPL may include at least one selected from lithium fluoride (LiF), silicon oxide (SiOx), silicon nitride (SiNx), and silicon oxynitride (SiOxNy). In an embodiment, the support layer SPL may include lithium fluoride (LiF) and may have the thickness t2 of about 400 Å and the refractive index n2 of about 1.4.

The first inorganic encapsulation layer TFEL1 may be disposed on the support layer SPL and have a refractive index greater than that of the support layer SPL. In an embodiment, for example, the first inorganic encapsulation layer TFEL1 may have a refractive index n3 of about 1.40 to about 1.50 and a thickness t3 of about 200 Å to about 1,600 Å. The first inorganic encapsulation layer TFEL1 may include at least one selected from silicon oxide (SiOx), silicon nitride (SiNx), and silicon oxynitride (SiOxNy). In an embodiment, the first inorganic encapsulation layer TFEL1 may include silicon nitride (SiNx), and may have a refractive index n3 of about 1.5, and a thickness t3 of about 1,000 Å.

The first organic encapsulation layer TFEL2 may be disposed on the first inorganic encapsulation layer TFEL1 to have a greater refractive index than that of the first inorganic encapsulation layer TFEL1. In an embodiment, for example, the first organic encapsulation layer TFEL2 may have a refractive index equal to or greater than about 1.50 and less than or equal to about 1.60 (or a refractive index of about 1.50 to about 1.60), and a thickness t4 of about 1 micrometer (μm) to about 8 μm. The first organic encapsulation layer TFEL2 may include an acrylic resin, such as polymethyl methacrylate and polyacrylic acid. In an embodiment, the first organic encapsulation layer TFEL2 may include a monomer, and may have the refractive index n4 of about 1.52, and the thickness t4 of about 8 μm.

The buffer layer BF-1 may be disposed directly on the first organic encapsulation layer TFEL2 and may have a greater refractive index than that of the first organic encapsulation layer TFEL2. The buffer layer BF-1 may be formed to have a thickness of 0.05 to 0.3 times the thickness of the second inorganic encapsulation layer TFEL3 to be described later. In an embodiment, for example, the buffer layer BF-1 may have a refractive index equal to or greater than about 1.60 and less than or equal to about 1.80 (that is, a refractive index of about 1.60 to about 1.80), and a thickness t5 of about 300 Å to about 500 Å. In an embodiment, the buffer layer BF-1 may have the refractive index of about 1.7 and the thickness t5 of about 400 Å.

The buffer layer BF-1 may include an inorganic film that can prevent the permeation of air or moisture. In an embodiment, the buffer layer BF-1 may have the refractive index n5 of about 1.7 and the thickness t5 of about 400 Å. The buffer layer BF-1 may be formed to have a same thickness t5 as the thickness t2 of the support layer SPL. The buffer layer BF-1 and the second inorganic encapsulation layer TFEL3 may be formed in a same chamber. Accordingly, the refractive index at the interface between the buffer layer BF-1 and the second inorganic encapsulation layer TFEL3 may gradually increase.

The second inorganic encapsulation layer TFEL3 may be disposed on the buffer layer BF-1 and have a higher refractive index than that of the buffer layer BF-1. The second inorganic encapsulation layer TFEL3 may include at least one selected from silicon oxide (SiOx), silicon nitride (SiNx), and silicon oxynitride (SiOxNy). The second inorganic encapsulation layer TFEL3 may have a refractive index that is equal to or greater than about 1.85 and less than or equal to about 1.95 (or a refractive index of about 1.85 to about 1.95). The second inorganic encapsulation layer TFEL3 is located at the outermost layer of the thin-film encapsulation layer TFEL, and is formed to have a thickness sufficient to reliably prevent the permeation of moisture. The second inorganic encapsulation layer TFEL3 may be formed to a thickness of about 6,000 Å to about 8,000 Å. In an embodiment, the second inorganic encapsulation layer TFEL3 may be formed of silicon nitride (SiNx), may have the refractive index n6 of about 1.89 and the thickness t6 of about 7,000 Å.

In such an embodiment, the display device 10 has a multilayer structure in which the capping layer CPL, the support layer SPL and the thin-film encapsulation layer TFEL are sequentially stacked on one another, and the layers have different refractive indices from each other, such that the capping layer CPL, the support layer SPL, the first inorganic encapsulation layer TFEL3, the first organic encapsulation layer TFEL2 and the second inorganic encapsulation layer TFEL3 come into contact with each other to form interfaces where light can be refracted or reflected. In such an embodiment, the buffer layer BF-1 formed of an inorganic material is disposed between the first organic encapsulation layer TFEL2 and the second inorganic encapsulation layer TFEL3 so that the buffer layer BF-1, the first organic encapsulation layer TFEL2 and the second inorganic encapsulation layer TFEL3 have different refractive indices from each other, thereby forming a plurality of reflective interfaces together with the capping layer CPL and the support layer SPL. The display device 10 according to an embodiment includes the above-described structure of the layers having different refractive indices from each other, so that it is possible to control the luminous efficiency of the light-emitting elements ED, the emission efficiency of the lights emitted from the light-emitting elements ED, and the viewing angles, thereby improving external light efficiency.

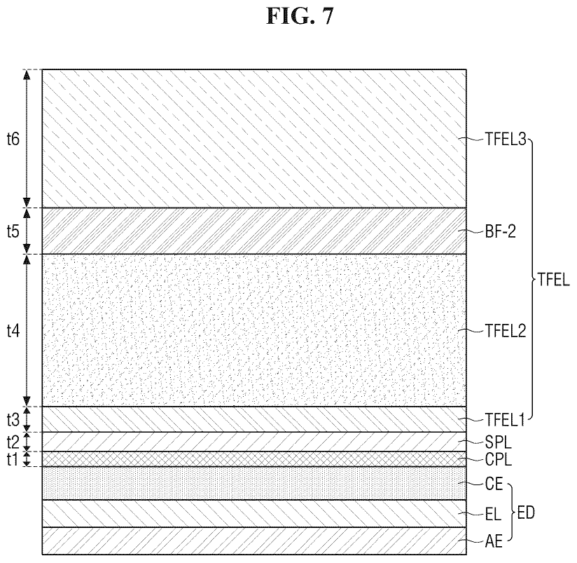

FIG. 7 is a cross-sectional view showing a stacked structure of a light-emitting element and an encapsulation layer of a display device according to an alternative embodiment.

The display device of FIG. 7 is substantially to the same as the display device of FIG. 6 except for a thin-film encapsulation layer TFEL; and, therefore, any repetitive detailed description of the same or like elements as those described above will be omitted.

The thin-film encapsulation layer TFEL may be disposed on a support layer SPL, and may include a first inorganic encapsulation layer TFEL1, a first organic encapsulation layer TFEL2, a buffer layer BF-2, and a second inorganic encapsulation layer TFEL3.

The first inorganic encapsulation layer TFEL1 may be disposed on the support layer SPL and have a refractive index greater than that of the support layer SPL. In an embodiment, for example, the first inorganic encapsulation layer TFEL1 may have a refractive index n3 of about 1.40 to about 1.50 and a thickness t3 of about 200 Å to about 1,600 Å. The first inorganic encapsulation layer TFEL1 may include at least one selected from silicon oxide (SiOx), silicon nitride (SiNx), and silicon oxynitride (SiOxNy). In an embodiment, the first inorganic encapsulation layer TFEL1 may include silicon nitride (SiNx), and may have a refractive index n3 of about 1.5, and a thickness t3 of about 1,000 Å.

The first organic encapsulation layer TFEL2 may be disposed on the first inorganic encapsulation layer TFEL1 to have a greater refractive index than that of the first inorganic encapsulation layer TFEL1. In an embodiment, for example, the first organic encapsulation layer TFEL2 may have a refractive index that is equal to or greater than about 1.50 and less than or equal to about 1.60, and a thickness t4 of about 1 μm to about 8 μm. The first organic encapsulation layer TFEL2 may include an acrylic resin, such as polymethyl methacrylate and polyacrylic acid. In an embodiment, the first organic encapsulation layer TFEL2 may include a monomer, and may have the refractive index n4 may be about 1.52, and the thickness t4 may be about 8 μm.

The buffer layer BF-2 may be disposed directly on the first organic encapsulation layer TFEL2 and may have a greater refractive index than that of the first organic encapsulation layer TFEL2. The buffer layer BF-2 may be formed to have a thickness of 0.05 to 0.3 times the thickness of the second inorganic encapsulation layer TFEL3 to be described later. In an embodiment, for example, the buffer layer BF-2 may have a refractive index that is equal to or greater than about 1.60 and less than or equal to about 1.80, and a thickness t5 of about 1600 Å to about 1800 Å.

The buffer layer BF-2 may include an inorganic layer that can prevent the permeation of air or moisture. In an embodiment, the buffer layer BF-2 may have the refractive index n5 of about 1.7 and the thickness t5 of about 1,700 Å. The buffer layer BF-2 and the second inorganic encapsulation layer TFEL3 may be formed in a same chamber. Accordingly, the refractive index at the interface between the buffer layer BF-2 and the second inorganic encapsulation layer TFEL3 may gradually increase.

The second inorganic encapsulation layer TFEL3 may be disposed on the buffer layer BF-2 and have a higher refractive index than that of the buffer layer BF-2. The second inorganic encapsulation layer TFEL3 may include at least one selected from silicon oxide (SiOx), silicon nitride (SiNx), and silicon oxynitride (SiOxNy). The second inorganic encapsulation layer TFEL3 may have a refractive index that is equal to or greater than about 1.85 and less than or equal to about 1.95. The second inorganic encapsulation layer TFEL3 is located at the outermost position of the thin-film encapsulation layer TFEL, and is formed to a thickness sufficient to reliably prevent the permeation of moisture. The second inorganic encapsulation layer TFEL3 may be formed to a thickness t6 of about 6,000 Å to about 8,000 Å. In an embodiment, the second inorganic encapsulation layer TFEL3 may include silicon nitride (SiNx), and may have the refractive index n6 of about 1.89 and the thickness t6 of about 7,000 Å.

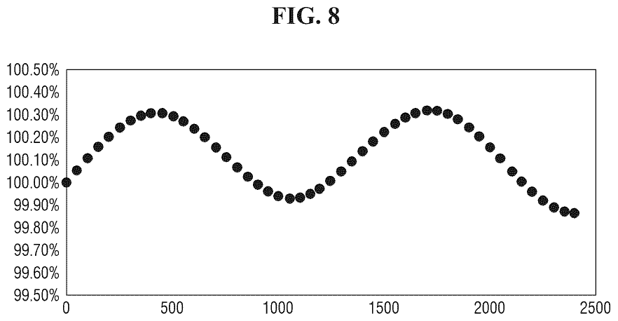

FIG. 8 is a graph showing results of a prediction simulation of a change in luminous efficiency depending on the thickness of a buffer layer.

In the prediction simulation of FIG. 8, the capping layer CPL has the refractive index n1 of 2.0 and the thickness t1 of 850 Å, the support layer SPL has the refractive index n2 of 1.4 and the thickness t2 of 400 Å, the first inorganic encapsulation layer TFEL3 has the refractive index n3 of 1.5 and the thickness t3 of 1,000 Å, the first organic encapsulation layer TFEL2 has the refractive index n4 of 1.52 and the thickness t4 of 8 μm, the buffer layer BF has the refractive index n5 of 1.7, and the second inorganic encapsulation layer TFEL3 had the refractive index n6 of 1.89 and the thickness t6 of 7,000 Å. In the prediction simulation, the thickness t5 of the buffer layer BF-1 was changed from 0 Å to 2,300 Å.

As can be seen from FIG. 8 that the thickness t2 of the buffer layer BF exhibited the highest luminous efficiency at about 400 Å and at about 1,700 Å. It can be seen from above that the optical distance condition that allows constructive interference can be satisfied when the thickness t2 of the buffer layer BF is about 400 Å and about 1700 Å under the simulation conditions.

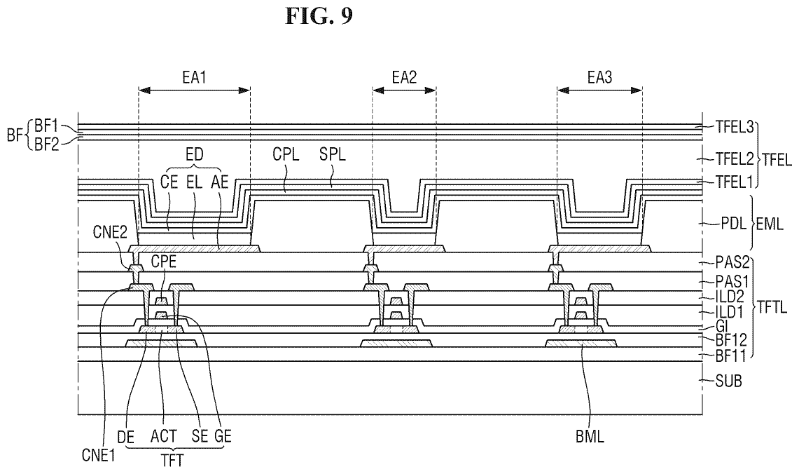

FIG. 9 is a cross-sectional view showing a part of a display device according to an alternative embodiment of the disclosure.

Referring to FIG. 9, in the display device 10 according to an embodiment, a buffer layer BF of a thin-film encapsulation layer TFEL may have a multilayer structure.

In an embodiment, as shown in FIG. 9, the buffer layer BF has a multilayer structure including a first buffer layer BF1 and a second buffer layer BF2 disposed on the first buffer layer BF1. It should be understood, however, that the number of the buffer layers BF may be variously modified. The embodiment of FIG. 9 is substantially to the same as the embodiments of FIGS. 5, 6 and 7 except that the buffer layer BF is defined by multiple layers.

In an embodiment of the display device 10, the buffer layer BF may be disposed between the first organic encapsulation layer TFEL2 and the second inorganic encapsulation layer TFEL3, and the buffer layer BF may include a first buffer layer BF1 disposed directly on the first organic encapsulation layer TFEL2 and a second buffer layer BF2 disposed on the first buffer layer BF1. The refractive indices of the first and second buffer layers BF1 and BF2 are greater than that of the first organic encapsulation layer TFEL2 and less than that of the second inorganic encapsulation layer TFEL3. The refractive index of the first buffer layer BF1 is different from that of the second buffer layer BF2.

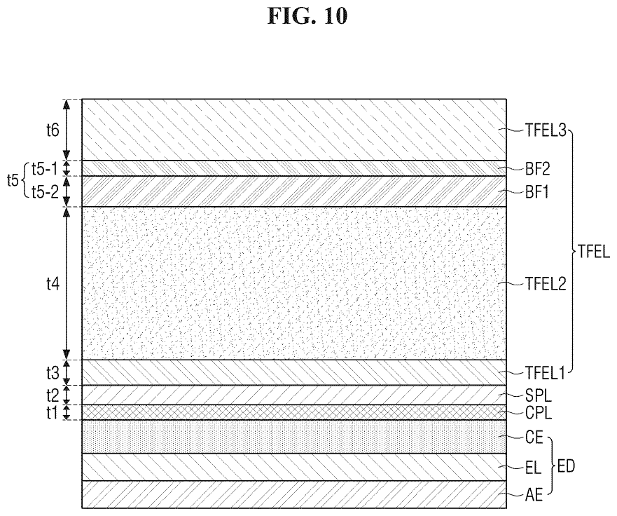

It should be noted that the total thickness t5 of the buffer layer BF having the multilayer structure may be adjusted to be in a range of about 1,400 Å to about 1,600 Å or about 2,700 Å to about 2,900 Å. Such an embodiment of the buffer layer BF will hereinafter be described in detail with reference to FIGS. 10 to 13.

FIGS. 10 to 13 are cross-sectional views showing a stacked structure of a light-emitting element and an encapsulation layer of a display device according to alternative embodiments. In embodiments shown in FIGS. 10 to 13, a buffer layer BF may include a first buffer layer BF1 and a second buffer layer BF2.

In an embodiment, referring to FIG. 10, the buffer layer BF may include the first buffer layer BF1 disposed directly on the first organic thin-film layer TFEL2, and a second buffer layer BF2 disposed on the first buffer layer BF1. The first buffer layer BF1 has a refractive index n5-1 that is equal to or greater than about 1.70 and less than or equal to about 1.80, and a thickness t5-1 of about 400 Å to about 600 Å. The second buffer layer BF2 has a refractive index n5-2 that is equal to or greater than about 1.60 and less than or equal to about 1.70, and a thickness t5-2 of about 900 Å to about 1,100 Å. According to an embodiment of the disclosure, the first buffer layer BF1 may have the refractive index n5-1 of about 1.77 and the thickness t-1 of about 500 Å, and the second buffer layer BF2 may have the refractive index n5-2 of about 1.62 and the thickness t5-2 of about 1,000 Å.

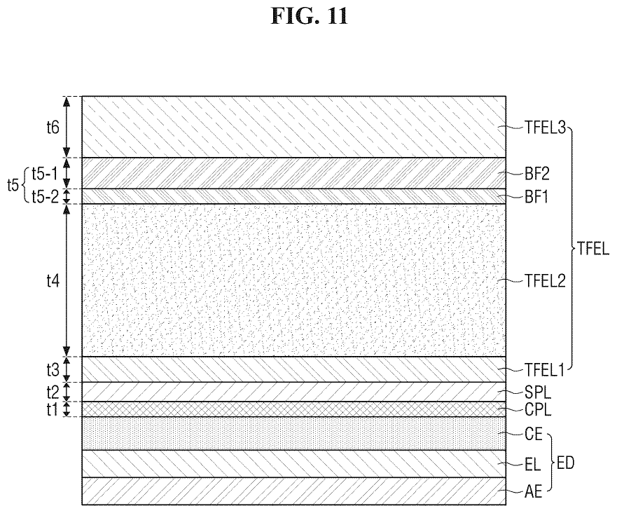

In an alternative embodiment, referring to FIG. 11, in the display device 10, the buffer layer BF may include the first buffer layer BF1 disposed directly on the first organic encapsulation layer TFEL2, and a second buffer layer BF2 disposed on the first buffer layer BF1. The first buffer layer BF1 has a refractive index n5-1 that is equal to or greater than about 1.60 and less than or equal to about 1.70, and a thickness t5-1 of about 900 Å to about 1,100 Å. The second buffer layer BF2 has a refractive index n5-2 that is equal to or greater than about 1.70 and less than or equal to about 1.80, and a thickness t5-2 of about 400 Å to about 600 Å. According to an embodiment of the disclosure, the first buffer layer BF1 may have the refractive index n5-1 of about 1.62 and the thickness t5-2 of about 1,000 Å, and the second buffer layer BF2 may have the refractive index n5-2 of about 1.77 and the thickness t5-1 of about 500 Å.

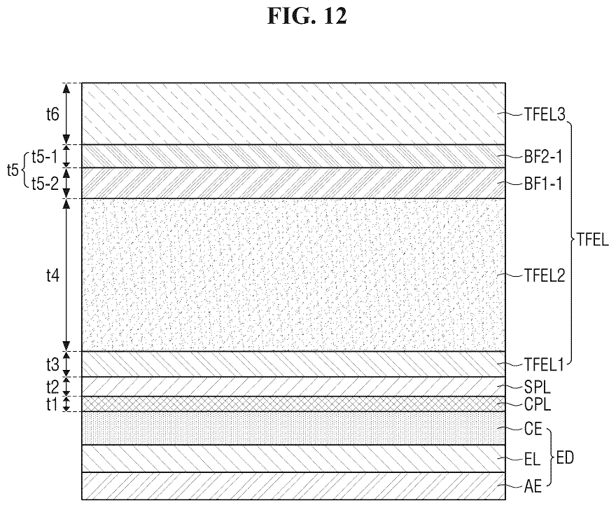

In another alternative embodiment, referring to FIG. 12, in the display device 10, the buffer layer BF may include a first buffer layer BF1-1 disposed directly on the first organic encapsulation layer TFEL2, and a second buffer layer BF2-1 disposed on the first buffer layer BF1-1. The first buffer layer BF1-1 may have a refractive index n5-1 that is equal to or greater than about 1.70 and less than or equal to about 1.80, and a thickness t5-2 of about 1,650 Å to about 1,850 Å. The second buffer layer BF2-1 may have a refractive index n5-2 that is equal to or greater than 1.60 and less than or equal to about 1.70, and a thickness t5-1 of about 1,000 Å to about 1,200 Å. According to an embodiment of the disclosure, the first buffer layer BF1-1 may have the refractive index n5-1 of about 1.77 and the thickness t5-2 of about 1,750 Å, and the second buffer layer BF2-1 may have the refractive index n5-2 of about 1.62 and the thickness t5-1 of about 1,100 Å.

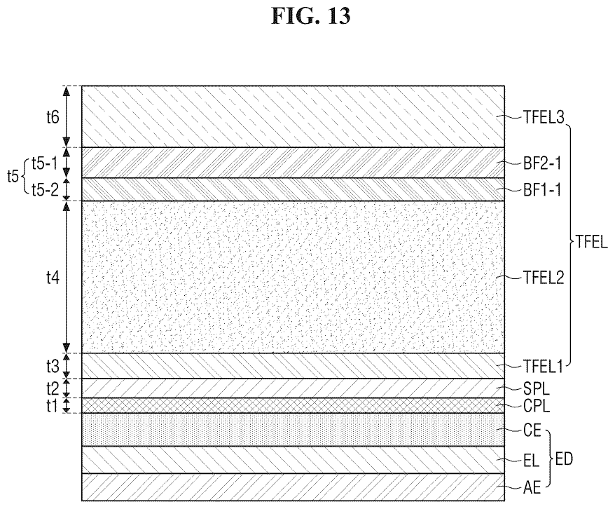

In another alternative embodiment, referring to FIG. 13, in the display device 10, the buffer layer BF may include a first buffer layer BF1-2 disposed directly on the first organic encapsulation layer TFEL2, and a second buffer layer BF2-2 disposed on the first buffer layer BF1-2. The first buffer layer BF1-2 may have a refractive index n5-1 that is equal to or greater than about 1.60 and less than or equal to about 1.70, and a thickness t5-11 of about 1,000 Å to about 1,200 Å. The second buffer layer BF2-2 may have a refractive index n5-2 that is equal to or greater than 1.70 and less than or equal to about 1.80, and a thickness t5-22 of about 1,650 Å to 1, about 850 Å. According to an embodiment of the disclosure, the first buffer layer BF1-2 may have the refractive index n5-1 of about 1.62 and the thickness t5-22 of about 1,100 Å, and the second buffer layer BF2-2 may have the refractive index n5-2 of about 1.77 and the thickness t5-11 of about 1,750 Å.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate;
a light-emitting element disposed on the substrate and comprising a pixel electrode, an emissive layer and a common electrode;
a capping layer disposed on the common electrode of the light-emitting element;
a support layer disposed on the capping layer; and
a thin-film encapsulation layer comprising a first inorganic encapsulation layer disposed on the support layer, a first organic encapsulation layer disposed on the first inorganic encapsulation layer, and a second inorganic encapsulation layer disposed on the first organic encapsulation layer,
wherein the thin-film encapsulation layer further comprises a buffer layer disposed between the first organic encapsulation layer and the second inorganic encapsulation layer, and the buffer layer comprises an inorganic material, and
wherein the buffer layer has a thickness of 0.05 times to 0.3 times of a thickness the second inorganic encapsulation layer.

2. The display device of claim 1, wherein
the second inorganic encapsulation layer has a thickness of about 6,000 Å to about 8,000 Å, and
the buffer layer has a thickness of about 300 Å to about 500 Å.

3. The display device of claim 1, wherein
the second inorganic encapsulation layer has a thickness of about 6,000 Å to about 8,000 Å, and
the buffer layer has a thickness of about 1,600 Å to about 1,800 Å.

4. The display device of claim 1, wherein the buffer layer has a refractive index greater than a refractive index of the first organic encapsulation layer and less than a refractive index of the second inorganic encapsulation layer.

5. The display device of claim 4, wherein the first organic encapsulation layer has a refractive index of about 1.50 to about 1.60,
wherein the buffer layer has a refractive index of about 1.60 to about 1.80, and
wherein the second inorganic encapsulation layer has a refractive index of about 1.85 to about 1.95.

6. The display device of claim 5, wherein the second inorganic encapsulation layer comprises silicon nitride (SiNx).

7. The display device of claim 1, wherein the thickness of the buffer layer is equal to that of the support layer.

8. The display device of claim 7, wherein the support layer has a thickness of about 300 Å to about 500 Å.

9. The display device of claim 1, wherein the support layer comprises lithium fluoride (LiF).

10. The display device of claim 1, wherein the buffer layer is disposed directly on the first organic encapsulation layer.

11. A display device comprising:
a substrate;
a light-emitting element disposed on the substrate and comprising a pixel electrode, an emissive layer and a common electrode;
a capping layer disposed on the common electrode of the light-emitting element;
a support layer disposed on the capping layer; and
a thin-film encapsulation layer comprising first inorganic encapsulation layer disposed on the support layer, a first organic encapsulation layer disposed on the first inorganic encapsulation layer, a buffer layer disposed on the first organic encapsulation layer, and a second inorganic encapsulation layer disposed on the buffer layer,
wherein the buffer layer comprises an inorganic material and has a multilayer structure including a first buffer layer and a second buffer layer having different refractive indices from each other.

12. The display device of claim 11, wherein
the first buffer layer has a refractive index greater than a refractive index of the first organic encapsulation layer, and
the second buffer layer has a refractive index greater than the refractive index of the first buffer layer.

13. The display device of claim 12, wherein the first organic encapsulation layer has a refractive index of about 1.50 to about 1.60,
wherein the first buffer layer has a refractive index of about 1.60 to about 1.70,
wherein the second buffer layer has a refractive index of about 1.70 to about 1.80, and
wherein the second inorganic encapsulation layer has a refractive index of about 1.85 to about 1.95.

14. The display device of claim 13, wherein the second inorganic encapsulation layer comprises silicon nitride (SiNx).

15. The display device of claim 11, wherein
the second inorganic encapsulation layer has a thickness of about 6,000 Å to about 8,000 Å, and
the buffer layer has a thickness of about 1,400 Å to about 1,600 Å.

16. The display device of claim 15, wherein
the first buffer layer has a thickness of about 900 Å to about 1,100 Å, and
the second buffer layer has a thickness of about 400 Å to about 600 Å.

17. The display device of claim 11, wherein
the second inorganic encapsulation layer has a thickness of about 6,000 Å to about 8,000 Å, and
the buffer layer has a thickness of about 2,650 Å to about 2,850 Å.

18. The display device of claim 17, wherein
the first buffer layer has a thickness of about 1,650 Å to about 1,850 Å, and
the second buffer layer has a thickness of about 1,000 Å to about 1,200 Å.

19. The display device of claim 15, wherein the support layer comprises lithium fluoride (LiF) and has a refractive index of 1.4.

20. The display device of claim 11, wherein
the first inorganic encapsulation layer has a refractive index of about 1.5, and
the capping layer has a refractive index of about 2.0.
